(19) United States
(12) Patent Application Publication
(10) Pub. No.: US 2025/0318050 A1
(43) Pub. Date: Oct. 9, 2025

(54) CIRCUIT BOARD, CIRCUIT BOARD ASSEMBLY, AND ELECTRONIC DEVICE

(71) Applicant: HONOR DEVICE CO., LTD., Shenzhen (CN)

(72) Inventors: Yawei ZHOU, Shenzhen (CN); Ye LV, Shenzhen (CN)

(21) Appl. No.: 18/863,441

(22) PCT Filed: Apr. 28, 2023
(86) PCT No.: PCT/CN2023/091770

§ 371 Date: Nov. 6, 2024

(30) Foreign Application Priority Data
Aug. 5, 2022 (CN) 202210938637.X

(51) Int. Cl. H05K 1/11

(52) U.S. Cl. CPC H05K 1/111; H05K 2201/09381; H05K 2201/094

(57) ABSTRACT

This application provides an electronic device. The electronic device comprises a first component, a second component and a circuit board. The circuit board includes a main board, a first type of solder pad, and a second type of solder pad. Both the first type of solder pad and the second type of solder pad are formed on a surface of the main board, and are electrically connected to the main board. The first type of solder pad includes a first solder pad and a first common solder pad, and the second type of solder pad includes a second solder pad and the first common solder pad. The first solder pad and the first common solder pad are configured to be simultaneously connected to the first component, and the second solder pad and the first common solder pad are configured to be simultaneously connected to the second component.

This application claims priority to Patent Application No. 202210938637.X, filed with the China National Intellectual Property Administration on Aug. 5, 2022, and entitled “CIRCUIT BOARD, CIRCUIT BOARD ASSEMBLY, AND ELECTRONIC DEVICE”, which is incorporated herein by reference in its entirety.

### TECHNICAL FIELD

This application relates to the field of communication technologies, and in particular, to a circuit board, a circuit board assembly, and an electronic device.

### BACKGROUND

In an electronic device such as a mobile phone, a main board is generally in elastic conduction with electronic components such as a motor and a speaker through elastic pieces, and positions of a solder pad and the elastic piece on the main board and a corresponding electronic component are relatively fixed in matching positions. When two electronic components such as motors are provided and have different directions, corresponding positions of the elastic pieces on the main board are different, so that different main boards are required to adapt to different electronic components, resulting in low utilization of the main board.

### SUMMARY

This application provides a circuit board, a circuit board assembly, and an electronic device, to resolve a technical problem of low utilization of a main board in the related art.

This application provides a circuit board. The circuit board is configured to arrange a first component or a second component. The circuit board includes a main board, a first type of solder pad, and a second type of solder pad. Both the first type of solder pad and the second type of solder pad are formed on a surface of the main board, and are electrically connected to the main board. The first type of solder pad includes a first solder pad and a first common solder pad, and the second type of solder pad includes a second solder pad and the first common solder pad. The first common solder pad includes a first side and a second side, and the first solder pad and the second solder pad are respectively located on the first side and the second side, and are spaced apart from the first common solder pad. The first solder pad and the first common solder pad are configured to be simultaneously connected to the first component, and the second solder pad and the first common solder pad are configured to be simultaneously connected to the second component.

In this embodiment, the first common solder pad is arranged, and the first common solder pad is used as both a part of the first type of solder pad and a part of the second type of solder pad, so that an area of a solder pad area can be reduced. In addition, when jointly used, the first common solder pad and the first solder pad may be configured to be connected to the first component, and when jointly used, the first common solder pad and the second solder pad may be configured to be connected to the second component, so that a same main board can be electrically connected to two different electronic components, and utilization of the main board is improved, thereby reducing costs. In addition, the first common solder pad is spaced apart from both the first solder pad and the second solder pad, so that a large deviation in a soldering position caused by solder floating during soldering can be avoided, accuracy of a soldering position of the elastic piece is improved, and stability of elastic connection of the elastic piece is ensured.

In a possible implementation, when the first solder pad and the first common solder pad are configured to be simultaneously connected to the first component, the second solder pad is vacant, and when the second solder pad and the first common solder pad are configured to be simultaneously connected to the second component, the first solder pad is vacant.

In this embodiment, when jointly used, the first common solder pad and the first solder pad may be configured to be connected to the first component, and when jointly used, the first common solder pad and the second solder pad may be configured to be connected to the second component, so that a same main board can be electrically connected to two different electronic components, and utilization of the main board is improved, thereby reducing costs.

In a possible implementation, a first gap is provided between the first solder pad and the first common solder pad, and an area of the first gap is less than or equal to 20% of a total area of the first solder pad, the first gap, and the first common solder pad.

It may be understood that the total area of the first solder pad, the first common solder pad, and the first gap is an original area of the first type of solder pad, and a total area of the first solder pad and the first common solder pad is an area occupied by a solder after the first type of solder pad is separated, that is, a soldering area. In this embodiment, the area of the first gap is less than or equal to 80% of the original area of the first type of solder pad. In other words, the soldering area of the first type of solder pad is set to be at least 80% of the original area of the first type of solder pad, thereby ensuring soldering strength.

In a possible implementation, a width of the first gap ranges from 0.15 mm to 0.25 mm. In this embodiment, the first gap is provided between the first solder pad and the first common solder pad, to prevent the solder from flowing between the first solder pad and the first common solder pad. In addition, when the first common solder pad is used as the second type of solder pad, when the elastic piece is soldered onto the second type of solder pad, a large deviation in a soldering position caused by drifting of the elastic piece toward the first solder pad can also be avoided. Therefore, the accuracy of the soldering position of the elastic piece is improved, and the stability of the elastic connection of the elastic piece is ensured, so that stability of an electrical connection between the electronic component and the main board is ensured.

In a possible implementation, a solder resist is arranged on the surface of the main board, and the solder resist is located in the first gap. In this embodiment, the first gap is filled with the solder resist, to prevent the solder from flowing between the first solder pad and the first common solder pad.

In a possible implementation, a length direction of the first type of solder pad intersects with a length direction of the second type of solder pad. In this embodiment, the length direction of the first type of solder pad intersects with the length direction of the second type of solder pad, so that the solder pad can be applied to two electronic components with different electrode directions, thereby further improving utilization of the circuit board.

In a possible implementation, the first solder pad includes a first sub-solder pad and a second sub-solder pad, the first sub-solder pad. The first common solder pad, and the second sub-solder pad are arranged side by side and spaced apart in the length direction of the first type of solder pad. The first common solder pad is located between the first sub-solder pad and the second sub-solder pad. The first side includes a first sub-side and a second sub-side. The first sub-solder pad is located on the first sub-side, and the second sub-solder pad is located on the second sub-side.

In this embodiment, the first solder pad is segmented into the first sub-solder pad and the second sub-solder pad, so that a distribution range of the first solder pad is increased, thereby improving adaptability of the first solder pad to the first component. In addition, in this embodiment, both the first sub-solder pad and the second sub-solder pad are spaced apart from the first common solder pad, so that the large deviation in the soldering position caused by solder floating during soldering can be avoided, the accuracy of the soldering position of the elastic piece is improved, and the stability of the elastic connection of the elastic piece is ensured.

In a possible implementation, the second solder pad includes a third sub-solder pad and a fourth sub-solder pad. The third sub-solder pad, the first common solder pad, and the fourth sub-solder pad are arranged side by side and spaced apart in the length direction of the second type of solder pad. The first common solder pad is located between the third sub-solder pad and the fourth sub-solder pad. The second side includes a third sub-side and a fourth sub-side. The third sub-solder pad is located on the third sub-side, and the fourth sub-solder pad is located on the fourth sub-side.

In this embodiment, the second solder pad is segmented into the third sub-solder pad and the fourth sub-solder pad, so that a distribution range of the second solder pad can be increased, thereby improving adaptability of the second solder pad to the second component.

In a possible implementation, a length direction of the first type of solder pad is parallel to a length direction of the second type of solder pad; and the first solder pad, the first common solder pad, and the second solder pad are arranged side by side and spaced apart in the length direction of the first type of solder pad, and the first common solder pad is located between the first solder pad and the second solder pad.

In this embodiment, the first solder pad, the first common solder pad, and the second solder pad are arranged in a straight line, so that the first type of solder pad and the second type of solder pad are applicable to two electronic components having a same electrode extension direction and different positions.

In a possible implementation, the main board includes a positive electrode circuit and a negative electrode circuit, the first common solder pad is electrically connected to the positive electrode circuit, and both the first solder pad and the second solder pad are insulated from the main board; or the first common solder pad is electrically connected to the negative electrode circuit, and both the first solder pad and the second solder pad are insulated from the main board.

In this embodiment, the first common solder pad is used as an electrical connection region, and other regions are only used as fixed connection regions, so that when jointly used, the first common solder pad and the first solder pad can be electrically connected to the first component, and when jointly used, the first common solder pad and the second solder pad can be electrically connected to the second component, thereby simplifying a structure of the solder pad.

In a possible implementation, the main board includes a positive electrode circuit and a negative electrode circuit, the first solder pad is electrically connected to the positive electrode circuit, the second solder pad is electrically connected to the negative electrode circuit, and the first common solder pad is insulated from the main board; or the first solder pad is electrically connected to the negative electrode circuit, the second solder pad is electrically connected to the positive electrode circuit, and the first common solder pad is insulated from the main board.

In this embodiment, the first common solder pad is set to be insulated from the main board, so that the first common solder pad is only used for fixed connection, and is not conductive, thereby avoiding a short circuit when the first type of solder pad and the second type of solder pad are separately connected to circuits of different polarities.

In a possible implementation, the second type of solder pad further includes a second common solder pad. The second common solder pad is spaced apart from the second solder pad and the first common solder pad. The second common solder pad, the second solder pad, and the first common solder pad are configured to be simultaneously connected to the second component. The circuit board further includes a third type of solder pad. The third type of solder pad is formed on the surface of the main board, and is arranged side by side with and spaced apart from the first type of solder pad. The third type of common solder pad includes a third solder pad and the second common solder pad. The third solder pad is spaced apart from the second common solder pad, and the second common solder pad and the third solder pad are configured to be simultaneously connected to the first component.

In this embodiment, the third type of solder pad is arranged, and the third type of solder pad and the first type of solder pad may be simultaneously connected to the first component. In actual application, the third type of solder pad and the first type of solder pad may be electrically connected to a positive electrode and a negative electrode of the first component respectively. In this way, a current loop is formed between the first component and the main board, so that the first component is electrically connected to the main board. In addition, in this embodiment, the second common solder pad is arranged, so that the second common solder pad is used as both a part of the second type of solder pad and a part of the third type of solder pad, thereby further reducing the area of the solder pad, saving space, and saving materials.

In a possible implementation, a third gap is provided between the first common solder pad and the second solder pad, and a fourth gap is provided between the second solder pad and the second common solder pad; and a total area of the third gap and the third gap is less than or equal to 20% of a total area of the first common solder pad, the second solder pad, the second common solder pad, the third gap, and the fourth gap.

In this embodiment, a total area of the second solder pad, the first common solder pad, and the second common solder pad is an actual soldering area of the second type of solder pad. The total area of the second solder pad, the first common solder pad, the second common solder pad, the third gap, and the fourth gap is an original area of the second type of solder pad. In this embodiment, a total area of the third gap and the third gap is less than or equal to 20% of the total area of the first common solder pad, the second solder pad, the second common solder pad, the third gap, and the fourth gap. In other words, a soldering area of the second type of solder pad is at least 80% of the original area of the second type of solder pad, thereby ensuring strength of soldering between the elastic piece and the second type of solder pad.

In a possible implementation, a region in which the first solder pad and the first common solder pad are located is a first region. A region in which the second solder pad, the first common solder pad, and the second common solder pad are located is a second region. At least one of a length and a width of the first region is different from a length of the second region, or is different from a width of the second region.

In this embodiment, sizes of the first region and the second region are different, so that the first region and the second region can be adapted to elastic pieces of different sizes, so that the first type of solder pad and the second type of solder pad can be used for soldering different electronic components, thereby improving applicability of the circuit board.

In a possible implementation, the third type of solder pad further includes a third common solder pad. The third common solder pad is spaced apart from the third solder pad and the second common solder pad. The third common solder pad, the third solder pad, and the second common solder pad are configured to be simultaneously connected to the first component. The circuit board further includes a fourth type of solder pad. The fourth type of solder pad is formed on the surface of the main board, and is arranged side by side with and spaced apart from the second type of solder pad. The fourth type of solder pad includes a fourth solder pad and the third common solder pad. The fourth solder pad is spaced apart from the third common solder pad, and the third common solder pad and the fourth solder pad are configured to be simultaneously connected to the second component.

In this embodiment, the fourth type of solder pad is arranged, and the fourth type of solder pad and the second type of solder pad may be simultaneously connected to the second component. In actual application, the fourth type of solder pad and the second type of solder pad may be electrically connected to a positive electrode and a negative electrode of the second component respectively. In this way, a current loop is formed between the second component and the main board, so that the second component is electrically connected to the main board. In addition, in this embodiment, the third common solder pad is arranged, so that the third common solder pad is used as both a part of the third type of solder pad and a part of the fourth type of solder pad, thereby further reducing the area of the solder pad, saving the space, and saving the materials.

In a possible implementation, the main board includes a positive electrode circuit and a negative electrode circuit, the first common solder pad is electrically connected to the positive electrode circuit, the third common solder pad is electrically connected to the negative electrode circuit, and the first solder pad, the second solder pad, the third solder pad, the fourth solder pad, and the third common solder pad are all insulated from the main board; or the first common solder pad is electrically connected to the negative electrode circuit, the third common solder pad is electrically connected to the positive electrode circuit, and the first solder pad, the second solder pad, the third solder pad, the fourth solder pad, and the third common solder pad are all insulated from the main board.

In this embodiment, the first common solder pad and the third common solder pad are used as electrical connection regions, and other regions are only used as fixed connection regions, so that the first component is electrically connected to the main board, and the second component is electrically connected to the main board, thereby simplifying the structure of the solder pad.

In a possible implementation, the main board includes a positive electrode circuit and a negative electrode circuit, the first solder pad, the first common solder pad, and the second solder pad are all electrically connected to the positive electrode circuit, the third solder pad, the fourth solder pad, and the third common solder pad are all electrically connected to the negative electrode circuit, and the second common solder pad is insulated from the main board; or the first solder pad, the first common solder pad, and the second solder pad are all electrically connected to the negative electrode circuit, the third solder pad, the fourth solder pad, and the third common solder pad are all electrically connected to the positive electrode circuit, and the second common solder pad is insulated from the main board.

In this embodiment, when the first component is connected to the first type of solder pad and the third type of solder pad, the first component is electrically connected to the main board through the first solder pad, the first common solder pad, and the third solder pad. When the second component is connected to the second type of solder pad and the fourth type of solder pad, the second component is electrically connected to the main board through the second solder pad, the first common solder pad, and the fourth solder pad. In addition, in this embodiment, the second common solder pad is set to be insulated from the main board, to avoid a short circuit when the second type of solder pad and the third type of solder pad are separately connected to circuits of different polarities.

In an embodiment, this application provides a circuit board assembly, including an elastic piece and the foregoing circuit board. The elastic piece is a first elastic piece or a second elastic piece. When the elastic piece is the first elastic piece, the first elastic piece is soldered onto the first solder pad and the first common solder pad; or when the elastic piece is the second elastic piece, the second elastic piece is soldered onto the second solder pad and the first common solder pad.

In this embodiment, when jointly used, the first common solder pad and the first solder pad can be used for soldering the first elastic piece, and when jointly used, the first common solder pad and the second solder pad can be used for soldering the second elastic piece. In other words, the circuit board provided in this embodiment can be used for soldering both the first elastic piece and the second elastic piece, so that utilization of the circuit board can be improved.

In an embodiment, this application provides an electronic device, including an electronic component and the foregoing circuit board assembly. The electronic component is a first component or a second component. When the elastic piece is the first elastic piece, the electronic component is the first component, and the first component is electrically connected to the first elastic piece; or when the elastic piece is the second elastic piece, the electronic component is the second component, and the second component is electrically connected to the second elastic piece.

The circuit board in the electronic device provided in this embodiment can be soldered with both the first elastic piece and the second elastic piece, so that the electronic device can select the different first component and second component according to different use scenarios, thereby improving applicability of the electronic device, to improve utilization of the circuit board assembly and reduce costs.

In conclusion, in this application, a first common solder pad is arranged, and a first common solder pad is used as both a part of a first type of solder pad and a part of a second type of solder pad, so that an area of a solder pad can be reduced. In addition, when jointly used, the first common solder pad and the first solder pad may be configured to be connected to the first component, and when jointly used, the first common solder pad and the second solder pad may be configured to be connected to the second component, so that a same main board can be electrically connected to two different electronic components, and utilization of the main board is improved, thereby reducing costs. In addition, the first common solder pad is spaced apart from both the first solder pad and the second solder pad, so that a large deviation in a soldering position caused by solder floating during soldering can be avoided, accuracy of a soldering position of the elastic piece is improved, and stability of elastic connection of the elastic piece is ensured.

### BRIEF DESCRIPTION OF DRAWINGS

To describe the technical solutions in the embodiments of this application or the background more clearly, the following briefly describes the accompanying drawings required for describing the embodiments of this application or the background.

FIG. 1 is a schematic diagram of a structure of an electronic device according to an embodiment of this application;

FIG. 2 is a schematic diagram of a partial structure of the electronic device shown in FIG. 1;

FIG. 3 is a schematic diagram of a structure of a circuit board assembly in the electronic device shown in FIG. 1 in a first scenario;

FIG. 4 is a schematic diagram of a structure of the circuit board assembly shown in FIG. 3 in a second scenario;

FIG. 5 is a schematic diagram of a structure of a circuit board in the circuit board assembly shown in FIG. 3;

FIG. 6 is a schematic enlarged view of a structure of a solder pad in the circuit board shown in FIG. 5;

FIG. 7 is a schematic diagram of a partial structure of a circuit board according to Embodiment 2 of this application;

FIG. 8 is a schematic diagram of a partial structure of a circuit board according to Embodiment 3 of this application; and

FIG. 9 is a schematic diagram of a partial structure of a circuit board according to Embodiment 4 of this application.

### DESCRIPTION OF EMBODIMENTS

The following describes the embodiments of this application with reference to the accompanying drawings in the embodiments of this application.

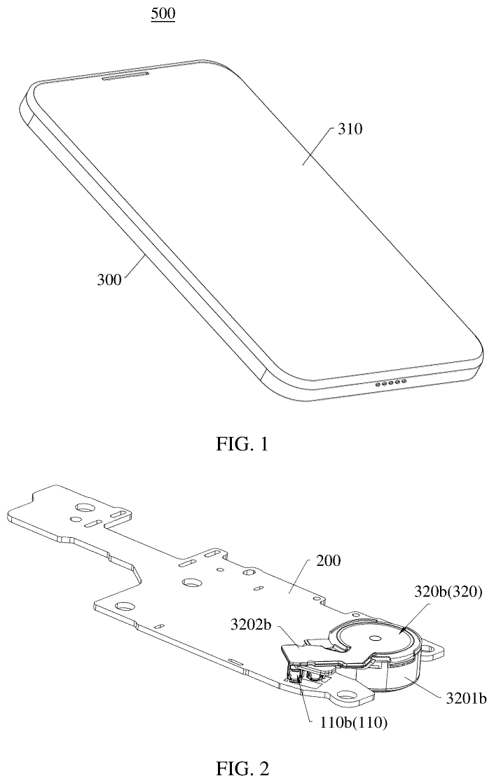

Refer to FIG. 1 and FIG. 2. FIG. 1 is a schematic diagram of a structure of an electronic device 500 according to an embodiment of this application, and FIG. 2 is a schematic diagram of a partial structure of the electronic device 500 shown in FIG. 1.

This application provides an electronic device 500. The electronic device 500 includes, but is not limited to, electronic products such as a cellphone (cellphone), a notebook computer (noteBook computer), a tablet personal computer (tablet personal computer), a laptop computer (laptop computer), a personal digital assistant (personal digital assistant, PDA), or a wearable device (wearable device). Descriptions are provided below by using an example in which the electronic device 500 is a cellphone.

The electronic device 500 includes a housing 300, a display screen 310, a circuit board assembly 200, and an electronic component 320. The display screen 310 is mounted on the housing 300, and encloses an accommodating space (not shown in the figure) with the housing 300. Both the circuit board assembly 200 and the electronic component 320 are located in the accommodating space and fixedly connected to the housing 300, and the electronic component 320 is electrically connected to the circuit board assembly 200. In this embodiment, the electronic component 320 is a motor. In other embodiments, the electronic component 320 may alternatively be a speaker or another electronic component. The electronic component 320 may be a first component (not shown in the figure), or may be a second component 320b. The electronic component 320 shown in FIG. 2 is the second component 320b.

The first component includes a first body, a first circuit board, and a first electrode (not shown in the figure). The first circuit board is a flexible printed circuit (Flexible Printed Circuit, FPC). The first electrode includes a first positive electrode and a first negative electrode. The first positive electrode and the first negative electrode are arranged side by side and spaced apart, and both the first positive electrode and the first negative electrode are arranged on the first circuit board and electrically connected to the first circuit board. The first circuit board is fixedly connected and electrically connected to the first body. The first electrode is configured to be electrically connected to the main board, so that the first component is electrically connected to the main board.

The second component 320b includes a second body 3201b, a second circuit board 3202b, and a second electrode (not marked in the figure). The second electrode includes a second positive electrode and a second negative electrode. The second positive electrode and the second negative electrode are arranged side by side and spaced apart, and both the second positive electrode and the second negative electrode are arranged on the second circuit board 3202b, and electrically connected to the second circuit board 3202b. The second circuit board 3202b is fixedly connected and electrically connected to the second body 3201b. The second electrode is configured to be electrically connected to the main board, so that the second component 320b is electrically connected to the main board.

The second component 320b and the first component may be a same type of electronic component in which a circuit board direction is inconsistent with an electrode direction, or may be different types of electronic components. In this embodiment, a difference between the second component 320b and the first component lies in that a position of the first circuit board relative to the first body is different from a position of the second circuit board 3202b relative to the second body 3201b, and orientations of the first electrode and the second electrode are different. In this embodiment, the first circuit board and the second circuit board 3202b are mirror symmetrical structures, and the first electrode and the second electrode are mirror symmetrical structures. In other words, when the first component and the second component 320b are mounted on the circuit board assembly 200, the first electrode and the second electrode correspond to different positions on the circuit board.

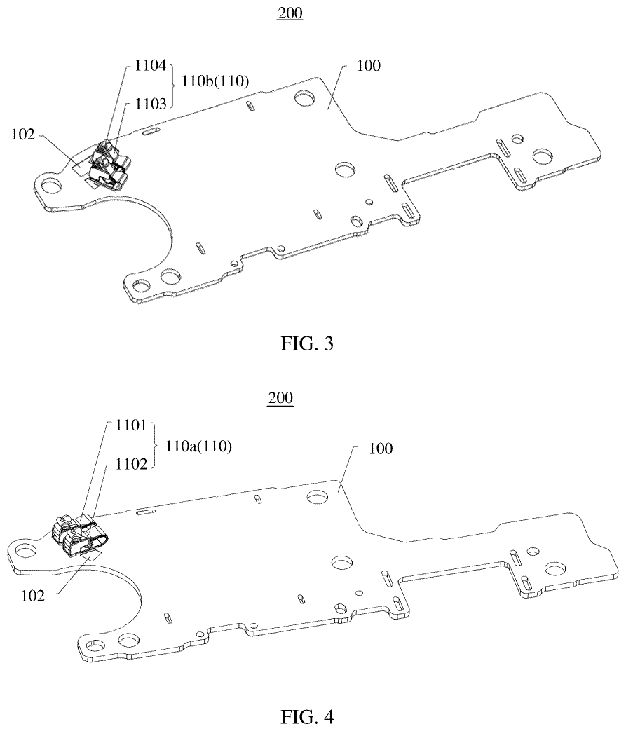

Refer to FIG. 3 and FIG. 4. FIG. 3 is a schematic diagram of a structure of the circuit board assembly 200 in the electronic device 500 shown in FIG. 1 in a first scenario, and FIG. 4 is a schematic diagram of a structure of the circuit board assembly 200 shown in FIG. 3 in a second scenario.

The circuit board assembly 200 includes a circuit board 100 and an elastic piece 110. The circuit board 100 includes a main board 101 and a solder pad 102. The solder pad 102 is arranged on a surface of the main board 101, and is electrically connected to the main board 101. The elastic piece 110 is soldered onto the solder pad 102, and is fixedly connected and electrically connected to the solder pad 102. The elastic piece 110 is configured to be electrically connected to the electronic component 320, so that the electronic component 320 is electrically connected to the main board 101. The elastic piece 110 may be a first elastic piece 110a or a second elastic piece 110b.

As shown in FIG. 3, in the first scenario, the electronic component 320 is the second component 320b, and the elastic piece 110 is the second elastic piece 110b. In this embodiment, the second elastic piece 110b includes a second positive elastic piece 1103 and a second negative elastic piece 1104. Both the second positive elastic piece 1103 and the second negative elastic piece 1104 are fixedly connected and electrically connected to the solder pad 102, and the second positive elastic piece 1103 and the second negative elastic piece 1104 are arranged side by side and spaced apart. The second positive elastic piece 1103 is configured to be electrically connected to the second positive electrode of the second component 320b, and the second negative elastic piece 1104 is configured to be electrically connected to the second negative electrode, so that the second component 320b is electrically connected to the main board 101.

As shown in FIG. 4, in the second scenario, the electronic component 320 is the first component, and the elastic piece 110 is the first elastic piece 110a. In this embodiment, the first elastic piece 110a includes a first positive elastic piece 1101 and a first negative elastic piece 1102. Both the first positive elastic piece 1101 and the first negative elastic piece 1102 are fixedly connected and electrically connected to the solder pad 102, and the first positive elastic piece 1101 and the first negative elastic piece 1102 are arranged side by side and spaced apart. The first positive elastic piece 1101 is configured to be electrically connected to the first positive electrode of the first component, and the first negative elastic piece 1102 is configured to be electrically connected to the first negative electrode, so that the first component is electrically connected to the main board 101.

The following specifically describes the structure of the circuit board 100.

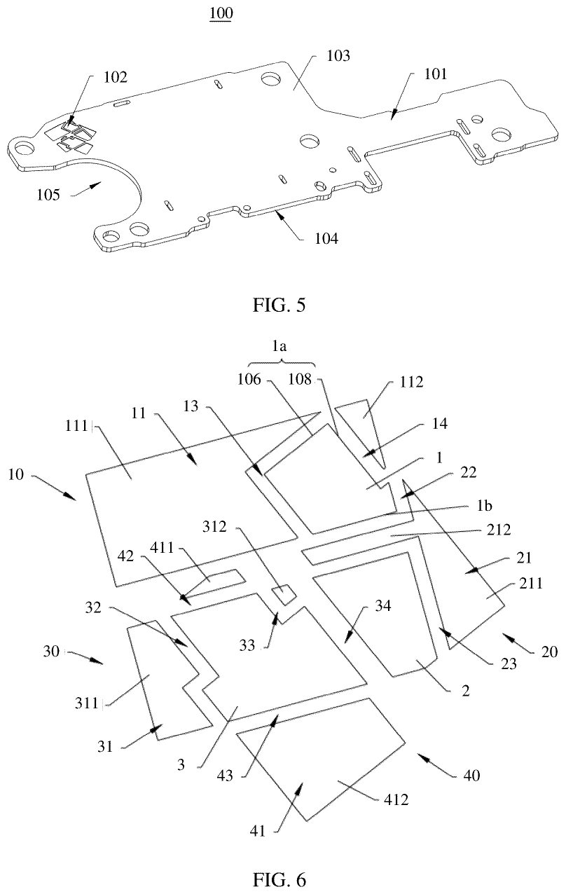

Refer to FIG. 5 and FIG. 6. FIG. 5 is a schematic diagram of the structure of the circuit board 100 in the circuit board assembly 200 shown in FIG. 3, and FIG. 6 is a schematic enlarged view of a structure of the solder pad 102 in the circuit board 100 shown in FIG. 5.

The circuit board 100 includes the main board 101 and the solder pad 102. The solder pad 102 is arranged on the main board 101, and is fixedly connected and electrically connected to the main board 101. In this embodiment, the main board 101 is a printed circuit board (Printed Circuit Board, PCB). In other embodiments, the main board 101 may alternatively be a flexible circuit board. The main board 101 includes a first surface 103 and a second surface 104. The first surface 103 is arranged opposite to the second surface 104. The main board 101 is provided with a mounting groove 105. The mounting groove 105 is provided on a side surface of the main board 101, and runs through the first surface 103 and the second surface 104. The mounting groove 105 is configured to mount the electronic component 320. A circuit is arranged on the main board 101. The circuit includes a positive electrode circuit and a negative electrode circuit (which are not shown in the figure). The solder pad 102 is arranged on the first surface 103 of the main board 101, and is electrically connected to the circuit of the main board 101.

The solder pad 102 includes a first type of solder pad 10, a second type of solder pad 20, a third type of solder pad 30, and a fourth type of solder pad 40. The first type of solder pad 10 and the third type of solder pad 30 are arranged side by side and spaced apart. In this embodiment, both an outer contour of the first type of solder pad 10 and an outer contour of the third type of solder pad 30 are rectangular. In other embodiments, the outer contour of the first type of solder pad 10 and the outer contour of the third type of solder pad 30 may alternatively be elliptical, circular, T-shaped, or may be in another shape. The first type of solder pad 10 and the third type of solder pad 30 are configured to be simultaneously connected to the first component. The second type of solder pad 20 and the fourth type of solder pad 40 are arranged side by side and spaced apart. In this embodiment, both an outer contour of the second type of solder pad 20 and an outer contour of the fourth type of solder pad 40 are T-shaped. In other implementations, the outer contour of the second type of solder pad 20 and the outer contour of the fourth type of solder pad 40 may alternatively be rectangular, elliptical, or may be in another shape. The second type of solder pad 20 and the fourth type of solder pad 40 are configured to be simultaneously connected to the second component 320b.

The first type of solder pad 10 includes a first solder pad 11 and a first common solder pad 1. The first common solder pad 1 includes a first side 1a and a second side 1b. The first solder pad 11 is located on the first side 1a. The first side 1a includes a first sub-side 106 and a second sub-side 108. The first solder pad 11 includes a first sub-solder pad 111 and a second sub-solder pad 112. The first sub-solder pad 111 is located on the first sub-side 106, and the second sub-solder pad 112 is located on the second sub-side 108. The first common solder pad 1 is located between the first sub-solder pad 111 and the second sub-solder pad 112, and is spaced apart from the first sub-solder pad 111 and the second sub-solder pad 112. A first gap is provided between the first solder pad 11 and the first common solder pad 1. The first gap includes a first sub-gap 13 and a second sub-gap 14. The first sub-gap 13 is a gap between the first sub-solder pad 111 and the first common solder pad 1. A width of the first sub-gap 13 ranges from 0.15 mm to 0.25 mm. The second sub-gap 14 is a gap between the second sub-solder pad 112 and the first common solder pad 1, and a width of the second sub-gap 14 ranges from 0.15 mm to 0.25 mm. The first sub-gap 13 and the second sub-gap 14 surround the first side 1a of the first common solder pad 1. It may be understood that the first sub-gap 13 and the second sub-gap 14 separate the first type of solder pad 10 into the first sub-solder pad 111, the second sub-solder pad 112, and the first common solder pad 1.

Both the first solder pad 11 and the first common solder pad 1 are solders. In this embodiment, the solder is a tin solder. In other embodiments, a material of the solder may alternatively be copper or silver. Both the first sub-gap 13 and the second sub-gap 14 are filled with a solder resist. In this embodiment, the gaps are provided between the first solder pad 11 and the first common solder pad 1, and the solder resist is arranged in the gaps, so that the first solder pad 11 can be separated from the first common solder pad 1, thereby preventing the solder from flowing between the first solder pad 11 and the first common solder pad 1.

In this embodiment, a proportion of a total area of the first solder pad 11 and the first common solder pad 1 to a total area of the first solder pad 11, the first common solder pad 1, the first sub-gap 13, and the second sub-gap 14 is greater than or equal to 80%. In other words, a total area of the first sub-gap 13 and the second sub-gap 14 is less than or equal to 20% of the total area of the first solder pad 11, the first common solder pad 1, the first sub-gap 13, and the second sub-gap 14. It may be understood that the total area of the first solder pad 11, the first common solder pad 1, the first sub-gap 13, and the second sub-gap 14 is an original area of the first type of solder pad 10, and the total area of the first solder pad 11 and the first common solder pad 1 is an area occupied by the solder after the first type of solder pad 10 is separated, that is, a soldering area. In this embodiment, the soldering area of the first type of solder pad 10 is set to at least 80% of the original area of the first type of solder pad 10, so that soldering strength can be ensured.

The second type of solder pad 20 includes the first common solder pad 1, a second common solder pad 2, and a second solder pad 21. The second solder pad 21 is located on the second side 1b of the first common solder pad 1, and is spaced apart from the first common solder pad 1. The second solder pad 21 includes a first extending body 211 and a second extending body 212. The first extending body 211 is fixedly connected to the second extending body 212. The first common solder pad 1 and the second common solder pad 2 are arranged side by side and spaced apart in a length direction of the second type of solder pad 20, the second common solder pad 2 and the first extending body 211 are arranged side by side in a width direction of the third type of solder pad 30, and the second extending body 212 is located between the first common solder pad 1 and the second common solder pad 2. A third gap 22 is provided between the second solder pad 21 and the first common solder pad 1. A width of the third gap 22 ranges from 0.15 mm to 0.25 mm. A fourth gap 23 is provided between the second solder pad 21 and the second common solder pad 2. A width of the fourth gap 23 ranges from 0.15 mm to 0.25 mm. It may be understood that the third gap 22 and the fourth gap 23 separate the second type of solder pad 20 into the second solder pad 21, the first common solder pad 1, and the second common solder pad 2.

The first common solder pad 1, the second common solder pad 2, and the second solder pad 21 are all solders. Both the third gap 22 and the fourth gap 23 are filled with the solder resist. In this embodiment, gaps are provided between the second solder pad 21 and the first common solder pad 1 and between the second solder pad 21 and the second common solder pad 2, and the solder resist is arranged in the gaps, so that the second solder pad 21 can be separated from the first common solder pad 1 and the second common solder pad 2, thereby preventing the solder from flowing between the second solder pad 21 and the first common solder pad 1 or flowing between the second solder pad 21 and the second common solder pad 2.

In this embodiment, a total area of the second solder pad 21, the first common solder pad 1, and the second common solder pad 2 is an actual soldering area of the second type of solder pad 20. A total area of the second solder pad 21, the first common solder pad 1, the second common solder pad 2, the third gap 22, and the fourth gap 23 is an original area of the second type of solder pad 20. In this embodiment, a soldering area of the second type of solder pad 20 is at least 80% of the original area of the second type of solder pad 20, so that the soldering strength can be ensured. In other words, a total area of the third gap 22 and the fourth gap 23 is less than or equal to 20% of the total area of the first common solder pad 1, the second solder pad 21, the second common solder pad 2, the third gap 22, and the fourth gap 23.

The length direction of the second type of solder pad 20 intersects with a length direction of the first type of solder pad 10. The first common solder pad 1 is a solder pad shared by the first type of solder pad 10 and the second type of solder pad 20. In other words, the first common solder pad 1 is used as both a part of the first type of solder pad 10 and a part of the second type of solder pad 20. The first common solder pad 1 and the first solder pad 11 are configured to be simultaneously connected to the first component. The first common solder pad 1, the second common solder pad 2, and the second solder pad 21 are configured to be simultaneously connected to the second component 320b. In this embodiment, the first common solder pad 1 is arranged, and the first common solder pad 1 is used as both a part of the first type of solder pad 10 and a part of the second type of solder pad 20, so that an area of the solder pad 102 can be reduced.

A region in which the first solder pad 11 and the first common solder pad 1 are located is a first region, and a region in which the second solder pad 21, the first common solder pad 1, and the second common solder pad 2 are located is a second region. In this embodiment, the first region and the second region have different lengths and widths. In other embodiments, the first region and the second region may have different lengths and a same width; or have a same width and different lengths.

Still refer to FIG. 6. The third type of solder pad 30 includes a third solder pad 31, the second common solder pad 2, and a third common solder pad 3. The third solder pad 31 includes a seventh sub-solder pad 311 and an eighth sub-solder pad 312. The seventh sub-solder pad 311, the third common solder pad 3, the eighth sub-solder pad 312, and the second common solder pad 2 are spaced apart in a length direction of the third type of solder pad 30. A first clearance 32 is provided between the seventh sub-solder pad 311 and the third common solder pad 3. A width of the first clearance 32 ranges from 0.15 mm to 0.25 mm. A second clearance 33 is provided between the eighth sub-solder pad 312 and the third common solder pad 3. A width of the second clearance 33 ranges from 0.15 mm to 0.25 mm. A third clearance 34 is provided between the second common solder pad 2, and the third common solder pad 3 and the eighth sub-solder pad 312. A width of the third clearance 34 ranges from 0.15 mm to 0.25 mm. It may be understood that, the first clearance 32, the second clearance 33, and the third clearance 34 separate the third type of solder pad 30 into four parts: the seventh sub-solder pad 311, the second common solder pad 2, the eighth sub-solder pad 312, and the third common solder pad 3.

The third solder pad 31, the second common solder pad 2, and the third common solder pad 3 are all solders. All the first clearance 32, the second clearance 33, and the third clearance 34 are filled with the solder resist. In this embodiment, the clearances are arranged between the third solder pad 31, the second common solder pad 2, and the third common solder pad 3, and the solder resist is arranged in the clearances, so that the third solder pad 31, the second common solder pad 2, and the third common solder pad 3 can be separated, thereby preventing the solder from flowing between any two adjacent regions of the third solder pad 31, the second common solder pad 2, and the third common solder pad 3.

In this embodiment, a total area of the third solder pad 31, the second common solder pad 2, and the third common solder pad 3 is an actual soldering area of the third type of solder pad 30. A total area of the third solder pad 31, the second common solder pad 2, the third common solder pad 3, the first clearance 32, the second clearance 33, and the third clearance 34 is an original area of the third type of solder pad 30. In this embodiment, a soldering area of the third type of solder pad 30 is at least 80% of the original area of the third type of solder pad 30, so that the soldering strength can be ensured. In other words, a total area of the first clearance 32, the second clearance 33, and the third clearance 34 is less than or equal to 20% of the total area of the third solder pad 31, the second common solder pad 2, the third common solder pad 3, the first clearance 32, the second clearance 33, and the third clearance 34.

As shown in FIG. 6, the length direction of the third type of solder pad 30 is parallel to the length direction of the first type of solder pad 10, and is arranged side by side with and spaced apart from the first type of solder pad 10. The length direction of the third type of solder pad 30 intersects with the length direction of the second type of solder pad 20. The second common solder pad 2 is the solder pad 102 shared by the second type of solder pad 20 and the third type of solder pad 30. In other words, the second common solder pad 2 is used as both a part of the second type of solder pad 20 and a part of the third type of solder pad 30. The second common solder pad 2, the first common solder pad 1, and the second solder pad 21 are configured to be simultaneously connected to the second component 320b. The second common solder pad 2, the third common solder pad 3, and the third solder pad 31 are configured to be simultaneously connected to the first component. In this embodiment, the second common solder pad 102 is arranged, and the second common solder pad 102 is used as both a part of the second type of solder pad 20 and a part of the third type of solder pad 30, so that the area of the solder pad 102 can be reduced.

The fourth type of solder pad 40 includes the third common solder pad 3 and a fourth solder pad 41. The fourth solder pad 41 includes a fifth sub-solder pad 411 and a sixth sub-solder pad 412. The fifth sub-solder pad 411, the third common solder pad 3, and the sixth sub-solder pad 412 are spaced apart in a length direction of the fourth type of solder pad 40, and the third common solder pad 3 is located between the fifth sub-solder pad 411 and the sixth sub-solder pad 412. A fourth clearance 42 is provided between the fifth sub-solder pad 411 and the third common solder pad 3. A width of the fourth clearance 42 ranges from 0.15 mm to 0.25 mm. A fifth clearance 43 is provided between the sixth sub-solder pad 412 and the third common solder pad 3. The width of the fifth clearance 43 ranges from 0.15 mm to 0.25 mm.

Both the third common solder pad 3 and the fourth solder pad 41 are solders. Both the fourth clearance 42 and the fifth clearance 43 are filled with the solder resist. In this embodiment, the clearances are provided between the fourth solder pad 41 and the third common solder pad 3, and the solder resist is arranged in the clearances, so that the fourth solder pad 41 and the third common solder pad 3 can be separated, thereby preventing the solder from flowing between the fourth solder pad 41 and the third common solder pad 3.

In this embodiment, a total area of the fourth solder pad 41 and the third common solder pad 3 is an actual soldering area of the fourth type of solder pad 40. A total area of the fourth solder pad 41, the third common solder pad 3, the fourth clearance 42, and the fifth clearance 43 is an original area of the fourth type of solder pad 40. In this embodiment, a soldering area of the fourth type of solder pad 40 is at least 80% of the original area of the fourth type of solder pad 40, so that the soldering strength can be ensured. In other words, a total area of the fourth clearance 42 and the fifth clearance 43 is less than or equal to 20% of the total area of the fourth solder pad 41, the third common solder pad 3, the fourth clearance 42, and the fifth clearance 43.

The length direction of the fourth type of solder pad 40 is parallel to the length direction of the second type of solder pad 20, and is arranged side by side with and spaced apart from the second type of solder pad 20. The length direction of the fourth type of solder pad 40 intersects with the length direction of the third type of solder pad 30. The third common solder pad 3 is the solder pad 102 shared by the third type of solder pad 30 and the fourth type of solder pad 40. In other words, the third common solder pad 3 is used as both a part of the third type of solder pad 30 and a part of the fourth type of solder pad 40. The third common solder pad 3 and the fourth solder pad 41 are configured to be simultaneously connected to the second component 320b. The third common solder pad 3, the second common solder pad 2, and the third solder pad 31 are configured to be simultaneously connected to the first component. In this embodiment, the third common solder pad 3 is arranged, and the third common solder pad 3 is used as both a part of the third type of solder pad 30 and a part of the fourth type of solder pad 40, so that the area of the solder pad 102 can be reduced.

The first type of solder pad 10 and the third type of solder pad 30 are configured to be simultaneously connected to the first component. In this case, the second solder pad 21 and the fourth solder pad 41 are vacant. The second type of solder pad 20 and the fourth type of solder pad 40 are configured to be simultaneously connected to the second component 320b. In this case, the first solder pad 11 and the third solder pad 31 are vacant. This embodiment may be implemented in the following implementations.

In a first implementation, the first sub-solder pad 111, the second sub-solder pad 112, the first common solder pad 1, and the second solder pad 21 are all electrically connected to the positive electrode circuit of the main board 101, and are used as a positive electrode of the main board 101. The seventh sub-solder pad 311, the eighth sub-solder pad 312, the fifth sub-solder pad 411, the sixth sub-solder pad 412, and the third common solder pad 3 are all electrically connected to the negative electrode circuit of the main board 101, and are used as a negative electrode of the main board 101. The second common solder pad 2 is insulated from the main board 101, and is not electrically connected to the positive electrode circuit of the main board 101 nor electrically connected to the negative electrode circuit of the main board 101. In other words, the second common solder pad 2 is used for fixed connection, and is neither used as the positive electrode of the main board 101 nor used as the negative electrode of the main board 101.

Refer to FIG. 4 and FIG. 6 together. When the electronic component 320 is the first component, the elastic piece 110 is the first elastic piece 110a. The first positive elastic piece 1101 is soldered onto the first type of solder pad 10, and the first negative elastic piece 1102 is soldered onto the third type of solder pad 30. The first positive electrode of the first component is electrically connected to the first positive elastic piece 1101, and the first negative electrode is electrically connected to the first negative elastic piece 1102. The first positive elastic piece 1101 is simultaneously soldered onto the first sub-solder pad 111, the first common solder pad 1, and the second sub-solder pad 112 of the first type of solder pad 10. The positive electrode circuit of the main board 101 is conducted to the first positive elastic piece 1101 simultaneously through the first sub-solder pad 111, the second sub-solder pad 112, and the first common solder pad 1, to be conducted to the first positive electrode of the first component. The first negative elastic piece 1102 is simultaneously soldered onto the seventh sub-solder pad 311, the eighth sub-solder pad 312, the second common solder pad 2, and the third common solder pad 3 of the third type of solder pad 30. The negative electrode circuit of the main board 101 is conducted to the first negative elastic piece 1102 simultaneously through the seventh sub-solder pad 311, the eighth sub-solder pad 312, and the third common solder pad 3, to be conducted to the first negative electrode of the first component, so that the first component is electrically connected to the main board 101.

Refer to FIG. 3 and FIG. 6 together. When the electronic component 320 is the second component 320b, the elastic piece 110 is the second elastic piece 110b. The second positive elastic piece 1103 is soldered onto the second type of solder pad 20, and the second negative elastic piece 1104 is soldered onto the fourth type of solder pad 40. The second positive electrode of the second component 320b is electrically connected to the second positive elastic piece 1103, and the second negative electrode is electrically connected to the second negative elastic piece 1104. The second positive elastic piece 1103 is simultaneously soldered onto the first common solder pad 1, the second solder pad 21, and the second common solder pad 2 of the second type of solder pad 20. The positive electrode circuit of the main board 101 is conducted to the second positive elastic piece 1103 simultaneously through the first common solder pad 1 and the second solder pad 21, to be conducted to the second positive electrode of the second component 320b. The second negative elastic piece 1104 is simultaneously soldered onto the fifth sub-solder pad 411, the third common solder pad 3, and the sixth sub-solder pad 412 of the fourth type of solder pad 40. The negative electrode circuit of the main board 101 is conducted to the second negative elastic piece 1104 simultaneously through the fifth sub-solder pad 411, the third common solder pad 3, and the sixth sub-solder pad 412, to be conducted to the second negative electrode of the second component 320b, so that the second component 320b is electrically connected to the main board 101.

In this embodiment, the first common solder pad 1, the second common solder pad 2, and the third common solder pad 3 are arranged. The first type of solder pad 10 and the second type of solder pad 20 share the first common solder pad 1, the second type of solder pad 20 and the third type of solder pad 30 share the second common solder pad 2, and the third type of solder pad 30 and the fourth type of solder pad 40 share the third common solder pad 3. The solder pad 102 is segmented, so that two different elastic pieces 110 can be soldered onto the solder pad 102. In this way, the same main board 101 can be electrically connected to two different electronic components 320, the area of the solder pad 102 is reduced, and utilization of the main board 101 is improved, thereby reducing costs. In addition, an area of each type of solder pad 102 is approximately the same as an area of the corresponding elastic piece 110, and the solder pad 102 is separated, so that a large deviation in a soldering position caused by solder floating during soldering can be avoided, accuracy of a soldering position of the elastic piece 110 is improved, and stability of elastic connection of the elastic piece 110 is ensured.

In addition, in this embodiment, the second common solder pad 2 is set to be insulated from the main board 101, so that the second common solder pad 2 is used only for fixed connection, and is not conductive, thereby avoiding a short circuit in the second common solder pad 2 when the second type of solder pad 20 is electrically connected to the positive electrode circuit, and the third type of solder pad 30 is electrically connected to the negative electrode circuit.

In a second implementation, a difference between this implementation and the first implementation lies in that the first sub-solder pad 111, the second sub-solder pad 112, the first common solder pad 1, and the second solder pad 21 are all electrically connected to the negative electrode circuit of the main board 101, and are used as the negative electrode of the main board 101. The seventh sub-solder pad 311, the eighth sub-solder pad 312, the fifth sub-solder pad 411, the sixth sub-solder pad 412, and the third common solder pad 3 are all electrically connected to the positive electrode circuit of the main board 101, and are used as the positive electrode of the main board 101. The second common solder pad 2 is insulated from the main board 101. When the electronic component 320 is the first component, the first positive elastic piece 1101 is soldered onto the third type of solder pad 30, and the first negative elastic piece 1102 is soldered onto the first type of solder pad 10. When the electronic component 320 is the second component 320b, the second positive elastic piece 1103 is soldered onto the fourth type of solder pad 40, and the second negative elastic piece 1104 is soldered onto the second type of solder pad 20.

In a third implementation, the first common solder pad 1 is electrically connected to the positive electrode circuit of the main board 101, and is used as the positive electrode of the main board 101. The third common solder pad 3 is electrically connected to the negative electrode circuit of the main board 101, and is used as the negative electrode of the main board 101. The first solder pad 11, the second solder pad 21, the third solder pad 31, the fourth solder pad 41, and the second common solder pad 2 are all insulated from the main board 101, are neither used as the positive electrode of the main board 101 nor used as the negative electrode of the main board 101, and is used for fixed connection.

When the electronic component 320 is the first component, the first positive elastic piece 1101 is soldered onto the first type of solder pad 10, and the first negative elastic piece 1102 is soldered onto the third type of solder pad 30. The positive electrode circuit of the main board 101 is conducted to the first positive elastic piece 1101 through the first common solder pad 1, to be conducted to the first positive electrode of the first component. The negative electrode circuit of the main board 101 is conducted to the first negative elastic piece 1102 through the third common solder pad 3, to be conducted to the first negative electrode of the first component, so that the first component is electrically connected to the main board 101.

When the electronic component 320 is the second component 320b, the second positive elastic piece 1103 is soldered onto the second type of solder pad 20, and the second negative elastic piece 1104 is soldered onto the fourth type of solder pad 40. The positive electrode circuit of the main board 101 is conducted to the second positive elastic piece 1103 through the first common solder pad 1, to be conducted to the second positive electrode of the second component 320b. The negative electrode circuit of the main board 101 is conducted to the second negative elastic piece 1104 through the third common solder pad 3, to be conducted to the second negative electrode of the second component 320b, so that the second component 320b is electrically connected to the main board 101.

In this embodiment, the first common solder pad 1 and the third common solder pad 3 are used as electrical connection regions, and other regions are only used as fixed connection regions, so that the first common solder pad 1 can electrically connect the first positive elastic piece 1101 to the main board 101, and electrically connect the second positive elastic piece 1103 to the main board 101. The third common solder pad 3 can electrically connect the first negative elastic piece 1102 to the main board 101 and electrically connect the second negative elastic piece 1104 to the main board 101, thereby simplifying the structure of the solder pad 102.

In a fourth implementation, a difference between this implementation and the third implementation lies in that the first common solder pad 1 is electrically connected to the negative electrode circuit of the main board 101, and is used as the negative electrode of the main board 101. The third common solder pad 3 is electrically connected to the positive electrode circuit of the main board 101, and is used as the positive electrode of the main board 101. The first solder pad 11, the second solder pad 21, the third solder pad 31, the fourth solder pad 41, and the second common solder pad 2 are all insulated from the main board 101. When the electronic component 320 is the first component, the first positive elastic piece 1101 is soldered onto the third type of solder pad 30, and the first negative elastic piece 1102 is soldered onto the first type of solder pad 10. When the electronic component 320 is the second component 320b, the second positive elastic piece 1103 is soldered onto the fourth type of solder pad 40, and the second negative elastic piece 1104 is soldered onto the second type of solder pad 20.

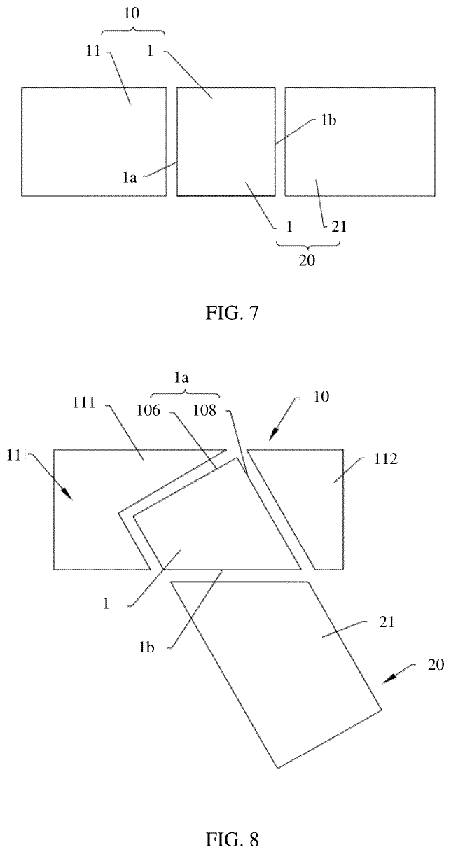

Refer to FIG. 7. FIG. 7 is a schematic diagram of a partial structure of a circuit board 100 according to Embodiment 2 of this application.

A difference between this embodiment and the embodiment shown in FIG. 5 lies in that the solder pad 102 includes the first type of solder pad 10 and the second type of solder pad 20. The first type of solder pad 10 includes the first solder pad 11 and the first common solder pad 1. The second type of solder pad 20 includes the first common solder pad 1 and the second solder pad 21. The length direction of the first type of solder pad 10 is parallel to the length direction of the second type of solder pad 20. The first common solder pad 1 includes the first side 1a and the second side 1b. The first side 1a and the second side 1b are arranged oppositely. The first solder pad 11, the first common solder pad 1, and the second solder pad 21 are arranged side by side and spaced apart in the length direction of the first type of solder pad 10, and the first common solder pad 1 is located between the first solder pad 11 and the second solder pad 21. The first solder pad 11 is located on the first side 1a, and the second solder pad 21 is located on the second side 1b. That is, the first solder pad 11, the first common solder pad 1, and the second solder pad 21 are arranged in a straight line. A width of a gap between the first common solder pad 1 and the first solder pad 11 ranges from 0.15 mm to 0.25 mm, and a width of a gap between the first common solder pad 1 and the second solder pad 21 ranges from 0.15 mm to 0.25 mm. Both the gap between the first common solder pad 1 and the first solder pad 11 and the gap between the first common solder pad 1 and the second solder pad 21 are filled with the solder resist, to separate the first common solder pad 1 from the first solder pad 11 and the second solder pad 21, preventing the solder from flowing between the first common solder pad 1 and the first solder pad 11 and between the first common solder pad 1 and the second solder pad 21.

The first solder pad 11 and the first common solder pad 1 are configured to be simultaneously connected to the first component. In this case, the second solder pad 21 is vacant. The second solder pad 21 and the first common solder pad 1 are configured to be simultaneously connected to the second component 320b. In this case, the first solder pad 11 is vacant. This embodiment may be implemented in the following implementations.

In a first implementation, the first solder pad 11, the first common solder pad 1, and the second solder pad 21 are all electrically connected to the positive electrode circuit of the main board 101, and are used as the positive electrode of the main board 101. When the electronic component 320 is the first component, the first positive elastic piece 1101 is simultaneously soldered onto and electrically connected to the first solder pad 11 and the first common solder pad 1, and the first positive electrode of the first component is conducted to the first positive elastic piece 1101, so that the first component is electrically connected to the main board 101. When the electronic component 320 is the second component 320b, the second positive elastic piece 1103 is simultaneously soldered onto and electrically connected to the second solder pad 21 and the first common solder pad 1, and the second positive electrode of the second component 320b is conducted to the second negative elastic piece 1104, so that the second component 320b is electrically connected to the main board 101.

In this embodiment, the first common solder pad 1 is arranged, and the first common solder pad 1 is used as both a part of the first type of solder pad 10 and a part of the second type of solder pad 20, so that the area of the solder pad 102 can be reduced. In addition, when jointly used, the first common solder pad 1 and the first solder pad 11 may be configured to be connected to the first component, and when jointly used, the first common solder pad 1 and the second solder pad 21 may be configured to be connected to the second component 320b, so that the same main board 101 can be electrically connected to two different electronic components 320, and utilization of the main board 101 is improved, thereby reducing costs. In addition, the first common solder pad 1 is spaced apart from both the first solder pad 11 and the second solder pad 21, so that the large deviation in the soldering position caused by the solder floating during soldering can be avoided, the accuracy of the soldering position of the elastic piece 110 is improved, and the stability of the elastic connection of the elastic piece 110 is ensured.

In a second implementation, a difference between this implementation and the first implementation lies in that the first solder pad 11, the first common solder pad 1, and the second solder pad 21 are all electrically connected to the negative electrode circuit of the main board 101, and are used as the negative electrode of the main board 101. When the electronic component 320 is the first component, the first negative elastic piece 1102 is simultaneously soldered onto and electrically connected to the first solder pad 11 and the first common solder pad 1. When the electronic component 320 is the second component 320b, the second negative elastic piece 1104 is simultaneously soldered onto and electrically connected to the second solder pad 21 and the first common solder pad 1.

In a third implementation, the first common solder pad 1 is electrically connected to the positive electrode circuit of the main board 101, and is used as the positive electrode of the main board 101. Both the first solder pad 11 and the second solder pad 21 are insulated from the main board 101. When the electronic component 320 is the first component, the first positive elastic piece 1101 is soldered onto the first type of solder pad 10, and is electrically connected to the first common solder pad 1, so that the main board 101 is conducted to the first positive electrode of the first component. When the electronic component 320 is the second component 320b, the second positive elastic piece 1103 is soldered onto the second type of solder pad 20, and is electrically connected to the first common solder pad 1, so that the main board 101 is conducted to the second positive electrode of the second component 320b.

In a fourth implementation, a difference between this implementation and the third implementation lies in that the first common solder pad 1 is electrically connected to the negative electrode circuit of the main board 101, and is used as the negative electrode of the main board 101. Both the first solder pad 11 and the second solder pad 21 are insulated from the main board 101.

In a fifth implementation, the first solder pad 11 is electrically connected to the positive electrode circuit of the main board 101, and is used as the positive electrode of the main board 101. The second solder pad 21 is electrically connected to the negative electrode circuit of the main board 101, and is used as the negative electrode of the main board 101. The first common solder pad 1 is insulated from the main board 101. When the electronic component 320 is the first component, the first positive elastic piece 1101 is soldered onto the first solder pad 11 and the first common solder pad 1, and is electrically connected to the first solder pad 11. The first positive electrode of the first component is electrically connected to the first positive elastic piece 1101, so that the first component is electrically connected to the main board 101. When the electronic component 320 is the second component 320b, the second negative elastic piece 1104 is soldered onto the second solder pad 21 and the second common solder pad 2, and is electrically connected to the second solder pad 21. The second negative electrode of the second component 320b is electrically connected to the second negative elastic piece 1104, so that the second component 320b is electrically connected to the main board 101.

In other implementations, the first solder pad 11 may alternatively be electrically connected to the negative electrode circuit of the main board 101, the second solder pad 21 is electrically connected to the positive electrode circuit of the main board 101, and the first common solder pad is insulated from the main board 101. In conclusion, when polarities of the first solder pad 11 and the second solder pad 21 are different, the first common solder pad 1 only needs to be insulated from the main board 101.

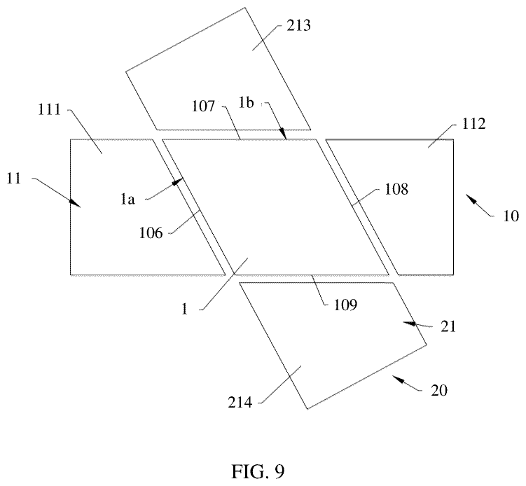

Refer to FIG. 8. FIG. 8 is a schematic diagram of a partial structure of a circuit board 100 according to Embodiment 3 of this application.

A difference between this embodiment and Embodiment 2 lies in that, in this embodiment, the length direction of the first type of solder pad 10 intersects with the length direction of the second type of solder pad 20. The first type of solder pad 10 includes the first sub-solder pad 111 and the second sub-solder pad 112. The first common solder pad 1 includes the first side 1a and the second side 1b. The first side 1a includes a first sub-side 106 and a second sub-side 108. The first sub-solder pad 111 is located on the first sub-side 106, and the second sub-solder pad 112 is located on the second sub-side 108. In the length direction of the first type of solder pad 10, the first sub-solder pad 111, the first common solder pad 1, and the second sub-solder pad 112 are arranged side by side and spaced apart. The second solder pad 21 is located on the second side 1b of the first common solder pad 1, and is arranged side by side with and spaced apart from the first common solder pad 1.

The first sub-solder pad 111, the first common solder pad 1, and the second sub-solder pad 112 are configured to be simultaneously connected to the first component, and the second solder pad 21 and the first common solder pad 1 are configured to be simultaneously connected to the second component 320b. In an implementation, the first sub-solder pad 111, the second sub-solder pad 112, the first common solder pad 1, and the second solder pad 21 are all electrically connected to the positive electrode circuit of the main board 101. When the electronic component 320 is the first component, the first positive elastic piece 1101 is simultaneously soldered onto and electrically connected to the first sub-solder pad 111, the first common solder pad 1, and the second sub-solder pad 112. The first positive elastic piece 1101 is electrically connected to the first positive electrode of the first component, so that the first component is electrically connected to the main board 101. When the electronic component 320 is the second component 320b, the second positive elastic piece 1103 is simultaneously soldered onto and electrically connected to the second solder pad 21 and the first common solder pad 1. The second positive elastic piece 1103 is electrically connected to the second positive electrode of the second component 320b, so that the second component 320b is electrically connected to the main board 101.

In other implementations, the first sub-solder pad 111, the second sub-solder pad 112, the first common solder pad 1, and the second solder pad 21 may alternatively be all electrically connected to the negative electrode circuit of the main board 101. Alternatively, the first common solder pad 1 is electrically connected to the positive electrode circuit or the negative electrode circuit of the main board 101, and the first sub-solder pad 111, the second sub-solder pad 112, and the second solder pad 21 are insulated from the main board 101. Alternatively, both the first sub-solder pad 111 and the second sub-solder pad 112 are electrically connected to the positive electrode circuit of the main board 101, the second solder pad 21 is electrically connected to the negative electrode circuit of the main board 101, the first common solder pad 1 is insulated from the main board 101, the first type of solder pad 10 is configured to be connected to the first positive elastic piece 1101, and the second type of solder pad 20 is configured to be connected to the second negative elastic piece 1104. Alternatively, both the second sub-solder pad 112 and the second sub-solder pad 112 are electrically connected to the negative electrode circuit of the main board 101, the second solder pad 21 is electrically connected to the positive electrode circuit of the main board 101, the first common solder pad 1 is insulated from the main board 101, the first type of solder pad 10 is configured to be connected to the first negative elastic piece 1102, and the second type of solder pad 20 is configured to be connected to the second positive elastic piece 1103.

In this embodiment, the first common solder pad 1 is arranged, and the first common solder pad 1 is used as both a part of the first type of solder pad 10 and a part of the second type of solder pad 20, so that the area of the solder pad 102 can be reduced. In addition, when jointly used, the first common solder pad 1 and the first solder pad 11 may be configured to be connected to the first component, and when jointly used, the first common solder pad 1 and the second solder pad 21 may be configured to be connected to the second component 320b, so that the same main board 101 can be electrically connected to two different electronic components 320, and utilization of the main board 101 is improved, thereby reducing costs. In addition, in this embodiment, the length direction of the first type of solder pad 10 intersects with the length direction of the second type of solder pad 20, so that the solder pad 102 can be applied to two different electronic components 320, thereby improving utilization of the circuit board 100.

Refer to FIG. 9. FIG. 9 is a schematic diagram of a partial structure of a circuit board 100 according to Embodiment 4 of this application.

A difference between this embodiment and Embodiment 3 lies in that, in this embodiment, the second solder pad 21 includes a third sub-solder pad 213 and a fourth sub-solder pad 214. The length direction of the first type of solder pad 10 intersects with the length direction of the second type of solder pad 20, jointly forming an X-shaped structure. The first common solder pad 1 is a parallelogram. The first common solder pad 1 includes the first side 1a and the second side 1b. The first side 1a includes the first sub-side 106 and the second sub-side 108. The second side 1b includes a third sub-side 107 and a fourth sub-side 109. The first sub-side 106, the third sub-side 107, the second sub-side 108, and the fourth sub-side 109 are connected end to end. The first sub-side 106 is arranged opposite to the second sub-side 108, and the third sub-side 107 is arranged opposite to the fourth sub-side 109. The seventh sub-solder pad 311, the first common solder pad 1, and the second sub-solder pad 112 are arranged side by side and spaced apart, and the first sub-solder pad 111 is located on a side of the first common solder pad 1 close to the first sub-side 106, and is spaced apart from the first sub-side 106. The second sub-solder pad 112 is located on a side close to the second sub-side 108, and is spaced apart from the second sub-side 108. The third sub-solder pad 213, the first common solder pad 1, and the fourth sub-solder pad 214 are arranged side by side and spaced apart. The third sub-solder pad 213 is located on a side of the first common solder pad 1 close to the third sub-side 107, and is spaced apart from the third sub-side 107. The fourth sub-solder pad 214 is located on a side close to the fourth sub-side 109, and is spaced apart from the fourth sub-side 109.

The first sub-solder pad 111, the first common solder pad 1, and the second sub-solder pad 112 are configured to be simultaneously connected to the first component. In this case, the third sub-solder pad 213 and the fourth sub-solder pad 214 are vacant. The third sub-solder pad 213, the fourth sub-solder pad 214, and the first common solder pad 1 are configured to be simultaneously connected to the second component 320b. In this case, the first sub-solder pad 111 and the second sub-solder pad 112 are vacant.

In this embodiment, the first common solder pad 1 is arranged, and the first common solder pad 1 is used as both a part of the first type of solder pad 10 and a part of the second type of solder pad 20, so that the area of the solder pad 102 can be reduced. In addition, when jointly used, the first common solder pad 1 and the first solder pad 11 may be configured to be connected to the first component, and when jointly used, the first common solder pad 1 and the second solder pad 21 may be configured to be connected to the second component 320b, so that the same main board 101 can be electrically connected to two different electronic components 320, and utilization of the main board 101 is improved, thereby reducing costs. In addition, in this embodiment, the length direction of the first type of solder pad 10 intersects with the length direction of the second type of solder pad 20, so that the solder pad 102 can be applied to two different electronic components 320, thereby improving utilization of the circuit board 100. In addition, the first common solder pad 1 is spaced apart from both the first solder pad 11 and the second solder pad 21, so that the large deviation in the soldering position caused by the solder floating during soldering can be avoided, the accuracy of the soldering position of the elastic piece 110 is improved, and the stability of the elastic connection of the elastic piece 110 is ensured.

The above descriptions are merely some embodiments and implementations of this application, and are not intended to limit the protection scope of this application. Any variation or replacement readily figured out by a person skilled in the art within the technical scope disclosed in this application shall fall within the protection scope of this application. Therefore, the protection scope of this application shall be subject to the protection scope of the claims.

1. An electronic device, comprising a first component, a second component and a circuit board;
wherein the circuit board comprises a main board, a first type of solder pad, and a second type of solder pad;
both the first type of solder pad and the second type of solder pad are formed on a surface of the main board, and are electrically connected to the main board;
the first type of solder pad comprises a first solder pad and a first common solder pad, and the second type of solder pad comprises a second solder pad and the first common solder pad; and
the first common solder pad comprises a first side and a second side, and the first solder pad and the second solder pad are respectively located on the first side and the second side, and are spaced apart from the first common solder pad; and
the first solder pad and the first common solder pad are configured to be simultaneously connected to the first component, and the second solder pad and the first common solder pad are configured to be simultaneously connected to the second component.

2. The electronic device according to claim 1, wherein when the first solder pad and the first common solder pad are configured to be simultaneously connected to the first component, the second solder pad is vacant, and when the second solder pad and the first common solder pad are configured to be simultaneously connected to the second component, the first solder pad is vacant.

3. The electronic device according to claim 1, wherein a first gap is provided between the first solder pad and the first common solder pad, and an area of the first gap is less than or equal to 20% of a total area of the first solder pad, the first gap, and the first common solder pad.

4. The electronic device according to claim 3, wherein a width of the first gap ranges from 0.15 mm to 0.25 mm.

5. The electronic device according to claim 4, wherein a solder resist is arranged on the surface of the main board, and the solder resist is located in the first gap.

6. The electronic device according to claim 1, wherein a length direction of the first type of solder pad intersects with a length direction of the second type of solder pad.

7. The electronic device according to claim 6, wherein the first solder pad comprises a first sub-solder pad and a second sub-solder pad, the first sub-solder pad, the first common solder pad, and the second sub-solder pad are arranged side by side and spaced apart in the length direction of the first type of solder pad, the first common solder pad is located between the first sub-solder pad and the second sub-solder pad, the first side comprises a first sub-side and a second sub-side, the first sub-solder pad is located on the first sub-side, and the second sub-solder pad is located on the second sub-side.

8. The electronic device according to claim 7, wherein the second solder pad comprises a third sub-solder pad and a fourth sub-solder pad, and the third sub-solder pad, the first common solder pad, and the fourth sub-solder pad are arranged side by side and spaced apart in the length direction of the second type of solder pad, the first common solder pad is located between the third sub-solder pad and the fourth sub-solder pad, the second side comprises a third sub-side and a fourth sub-side, the third sub-solder pad is located on the third sub-side, and the fourth sub-solder pad is located on the fourth sub-side.

9. The electronic device according to claim 1, wherein a length direction of the first type of solder pad is parallel to a length direction of the second type of solder pad; and the first solder pad, the first common solder pad, and the second solder pad are arranged side by side and spaced apart in the length direction of the first type of solder pad, and the first common solder pad is located between the first solder pad and the second solder pad.

10. The electronic device according to claim 1, wherein the main board comprises a positive electrode circuit and a negative electrode circuit, the first common solder pad is electrically connected to the positive electrode circuit, and both the first solder pad and the second solder pad are insulated from the main board; or the first common solder pad is electrically connected to the negative electrode circuit, and both the first solder pad and the second solder pad are insulated from the main board.

11. The electronic device beard according to claim 1, wherein the main board comprises a positive electrode circuit and a negative electrode circuit, the first solder pad is electrically connected to the positive electrode circuit, the second solder pad is electrically connected to the negative electrode circuit, and the first common solder pad is insulated from the main board; or the first solder pad is electrically connected to the negative electrode circuit, the second solder pad is electrically connected to the positive electrode circuit, and the first common solder pad is insulated from the main board.

12. The electronic device according to claim 1, wherein the second type of solder pad further comprises a second common solder pad, the second common solder pad is spaced apart from the second solder pad and the first common solder pad, and the second common solder pad, the second solder pad, and the first common solder pad are configured to be simultaneously connected to the second component; and
the circuit board further comprises a third type of solder pad, the third type of solder pad is formed on the surface of the main board, and is arranged side by side with and spaced apart from the first type of solder pad, the third type of solder pad comprises a third solder pad and the second common solder pad, the third solder pad is spaced apart from the second common solder pad, and the second common solder pad and the third solder pad are configured to be simultaneously connected to the first component.

13. The electronic device according to claim 12, wherein a third gap is provided between the first common solder pad and the second solder pad, and a fourth gap is provided between the second solder pad and the second common solder pad; and a total area of the third gap and the fourth gap is less than or equal to 20% of a total area of the first common solder pad, the second solder pad, the second common solder pad, the third gap, and the fourth gap.

14. The electronic device according to claim 12, wherein a region in which the first solder pad and the first common solder pad are located is a first region, a region in which the second solder pad, the first common solder pad, and the second common solder pad are located is a second region, and at least one of a length and a width of the first region is different from a length of the second region, or is different from a width of the second region.

15. The electronic device according to claim 12, wherein the third type of solder pad further comprises a third common solder pad, the third common solder pad is spaced apart from the third solder pad and the second common solder pad, and the third common solder pad, the third solder pad, and the second common solder pad are configured to be simultaneously connected to the first component; and
the circuit board further comprises a fourth type of solder pad, the fourth type of solder pad is formed on the surface of the main board, and is arranged side by side with and spaced apart from the second type of solder pad, the fourth type of solder pad comprises a fourth solder pad and the third common solder pad, the fourth solder pad is spaced apart from the third common solder pad, and the third common solder pad and the fourth solder pad are configured to be simultaneously connected to the second component.

16. The electronic device according to claim 15, wherein the main board comprises a positive electrode circuit and a negative electrode circuit, the first common solder pad is electrically connected to the positive electrode circuit, the third common solder pad is electrically connected to the negative electrode circuit, and the first solder pad, the second solder pad, the third solder pad, the fourth solder pad, and the third common solder pad are all insulated from the main board; or the first common solder pad is electrically connected to the negative electrode circuit, the third common solder pad is electrically connected to the positive electrode circuit, and the first solder pad, the second solder pad, the third solder pad, the fourth solder pad, and the third common solder pad are all insulated from the main board.

17. The electronic device according to claim 15, wherein the main board comprises a positive electrode circuit and a negative electrode circuit, the first solder pad, the first common solder pad, and the second solder pad are all electrically connected to the positive electrode circuit, the third solder pad, the fourth solder pad, and the third common solder pad are all electrically connected to the negative electrode circuit, and the second common solder pad is insulated from the main board; or the first solder pad, the first common solder pad, and the second solder pad are all electrically connected to the negative electrode circuit, the third solder pad, the fourth solder pad, and the third common solder pad are all electrically connected to the positive electrode circuit, and the second common solder pad is insulated from the main board.

18. The electronic device according to claim 1, wherein electronic device further comprises a first elastic piece and a second elastic piece;
the first elastic piece is soldered onto the first solder pad and the first common solder pad, the second elastic piece is soldered onto the second solder pad and the first common solder pad.

19. The electronic device according to claim 18, wherein the first component is electrically connected to the first elastic piece, and the second component is electrically connected to the second elastic piece.
